(19) United States
(12) Patent Application Publication
(10) Pub. No.: US 2024/0224729 A1
(43) Pub. Date: Jul. 4, 2024

(54) DISPLAY DEVICE

(71) Applicant: LG Display Co., Ltd., Seoul (KR)

(72) Inventor: HaeJoon SON, Paju-si (KR)

(73) Assignee: LG Display Co., Ltd., Seoul (KR)

(21) Appl. No.: 18/399,573

(22) Filed: Dec. 28, 2023

(30) Foreign Application Priority Data
Dec. 30, 2022 (KR) 10-2022-0191172
Dec. 26, 2023 (KR) 10-2023-0191344

(51) Int. Cl. H10K 59/80

(52) U.S. Cl. CPC H10K 59/873; H10K 59/874

(57) ABSTRACT

A display device may include a first substrate and a second substrate. The first substrate may include an active area in which a light emitting element is disposed and a non-active area surrounding the active area. The second substrate may be disposed on the first substrate. The display device may further include an adhesive layer disposed between the first substrate and the second substrate. The display device may include a coating layer disposed to contact a portion of the first substrate, a portion of the second substrate, and a portion of the adhesive layer.

### CROSS-REFERENCE TO RELATED APPLICATIONS

This application claims the benefit of and priority to Korean Patent Application No. 10-2022-0191172 filed on Dec. 30, 2022 and Korean Patent Application No. 10-2023-0191344 filed on Dec. 26, 2023, in the Republic of Korea, the entire contents of which are hereby expressly incorporated by reference into the present application.

### BACKGROUND

### Technical Field

The present disclosure relates to a display device, and more particularly, to a display device that minimizes penetration of moisture and oxygen, resulting in an improved lifespan and reliability.

### Discussion of the Related Art

Recently, as our society advances toward an information-oriented society, the field of display devices for visually expressing an electrical information signal has rapidly advanced. Various display devices having excellent performance in terms of thinness, lightness, and low power consumption, are thus being developed.

Representative display devices may include a liquid crystal display device (LCD), an electro-wetting display device (EWD), an organic light emitting display device (OLED), and the like.

Among the display devices, an OLED device is a self-luminous display device and can be manufactured to be light and thin since it does not require a separate light source, unlike a LCD device, which includes a separate light source. In addition, the OLED device has advantages in terms of power consumption due to a low voltage driving, and is excellent in terms of a color implementation, a response speed, a viewing angle, and a contrast ratio (CR). Therefore, OLED devices have been expected to be used in various application fields.

However, the OLED device has a limitation in which an organic layer constituting a light emitting element is very vulnerable to heat, moisture, and oxygen. Accordingly, an encapsulation technology for preventing penetration of moisture and oxygen into an inside of the OLED device is being desired.

### SUMMARY

Accordingly, embodiments of the present disclosure are directed to a display device that substantially obviates one or more of the problems due to limitations and disadvantages of the related art.

An aspect of the present disclosure is to provide a display device that minimizes introduction of moisture and oxygen through a side surface thereof.

Another aspect of the present disclosure is to provide a display device having improvements in lifespan and reliability.

Still another aspect of the present disclosure is to provide a display device that minimizes damage to a chip-on-film (COF) during a COF bonding process.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described, a display device may include a first substrate and a second substrate. The first substrate may include an active area in which a light emitting element is disposed and a non-active area surrounding the active area. The second substrate may be disposed on the first substrate. The display device may further include a coating layer disposed to contact a portion of the first substrate, a portion of the second substrate, and a portion of the adhesive layer.

In some embodiments, the display device may further include an adhesive layer disposed between the first substrate and the second substrate. The coating layer may be disposed to contact a portion of the adhesive layer.

In some embodiments, the coating layer may be disposed on the end portion of the first substrate, the end portion of the second substrate, and the end portion of the adhesive layer. The coating layer may cover at least a portion of an upper surface of the second substrate corresponding to the non-active area.

In some embodiments, the coating layer may cover an entire surface of the second substrate corresponding to the active area and the non-active area.

In some embodiments, the display device may further include a passivation layer disposed over the light emitting element, the passivation layer being formed of an inorganic material.

In some embodiments, the coating layer is configured to prevent penetration of moisture and/or oxygen.

In some embodiments, the display device may further include a dam part surrounding the adhesive layer and disposed in the non-active area. The dam part may include a moisture absorption layer disposed within an interior of the dam part and extending along a longitudinal axis. The dam part may further include base dam portion surrounding the moisture absorption layer such that the moisture absorption layer is disposed within the base dam portion. The base dam portion may have a cylindrical shape. In other embodiments, the base dam portion may have a quadrangular shape and the moisture absorption layer may have any one of a circular shape, a quadrangular shape, and a polygonal shape. The base dam portion may be made of at least one of an epoxy-based sealing material and an acrylic-based sealing material and the moisture absorption layer may be made of a moisture adsorbent. The base dam portion may be configured to block penetration of moisture and/or oxygen while reinforcing adhesiveness between the first substrate and the second substrate.

In some embodiments, the display device may further include a thin film encapsulation layer disposed over the light emitting element and having a plurality of inorganic layers and a plurality of organic layers. The plurality of inorganic layers and the plurality of organic layers of the thin film encapsulation layer may be alternately disposed.

According to certain embodiments, a display device may include a first substrate, a second substrate, and a side sealing part. The first substrate may include an active area in which a light emitting element is disposed and a non-active area surrounding the active area. The second substrate may be disposed above the first substrate. The side sealing part may be positioned such that side sealing part covers a space between the first substrate and the second substrate, a portion of an upper surface of the second substrate, and a side surface of an end portion of the first substrate.

In some embodiments, the display device further includes a polarizing plate disposed under the first substrate and having an end portion thereof located outside the first substrate and thin film encapsulation layer disposed on the light emitting element and having a plurality of inorganic layers and a plurality of organic layers. The plurality of inorganic layers and the plurality of organic layers of the thin film encapsulation layer may be alternately disposed.

In some embodiments, the side sealing part may include a first side sealing portion, a second side sealing portion, and a third side sealing portion. The first side sealing portion may be positioned to cover the portion of the upper surface of the second substrate and the space between the first and second substrates. The second side sealing portion may be positioned to cover the end portion of the first substrate while covering a portion of an upper surface of the first substrate. The third side sealing portion may be disposed between the first side sealing portion and the second side sealing portion. The first side sealing portion may be of a frit sealing material and the second side sealing portion and the third side sealing portion may be made of at least one of an epoxy-based resin and an acrylic-based resin.

In some embodiments, the display device may include a passivation layer made of an inorganic material under the thin film encapsulation layer.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles.

In the drawings:

FIG. 1 is a plan view of a display device according to an example embodiment of the present disclosure.

FIG. 2 is a cross-sectional view of a sub-pixel of the display device according to an example embodiment of the present disclosure.

FIGS. 3A to 3E are cross-sectional views taken along III-III′ of FIG. 1.

FIGS. 4A to 4E are other cross-sectional views taken along III-III′ of FIG. 1.

FIG. 5 is a plan view of a display device according to another example embodiment of the present disclosure.

FIGS. 6A and 6B are cross-sectional views taken along VI-VI′ of FIG. 5.

FIGS. 6C and 6D are another cross-sectional views taken along VI-VI′ of FIG. 5.

FIG. 7 is a plan view of a display device according to another example embodiment of the present disclosure.

FIG. 8 is a cross-sectional view taken along VIII-VIII′ of FIG. 7.

FIG. 9A is a perspective view illustrating an arrangement of a dam part according to another example embodiment of the present disclosure.

FIG. 9B is a cross-sectional view of the dam part of FIG. 9A.

### DETAILED DESCRIPTION OF THE EMBODIMENTS

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

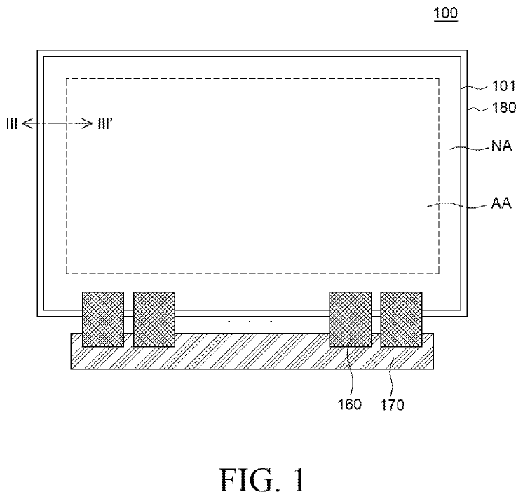

FIG. 1 is a plan view of a display device according to an example embodiment of the present disclosure.

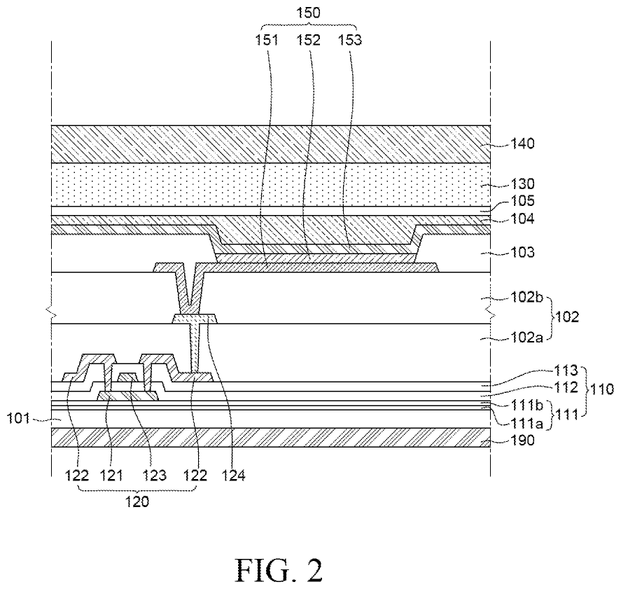

FIG. 2 is a cross-sectional view of a sub-pixel of the display device according to an example embodiment of the present disclosure.

FIG. 1 illustrates a first substrate 101, a plurality of flexible films 160, a printed circuit board 170, and a moisture barrier coating layer 180 among various components of the display device 100 for convenience of description.

Referring to FIG. 1, the first substrate 101 is a support member for supporting other components of the display device 100. A plurality of pixels for displaying an image, driving elements for driving the plurality of pixels, and lines for transmitting various signals to the plurality of pixels and driving elements may be disposed on the first substrate 101. The first substrate 101 may include an active area AA and a non-active area NA. The active area AA may be an area where the plurality of pixels are disposed to substantially display an image. A plurality of sub-pixels constituting the plurality of pixels and circuits for driving the plurality of sub-pixels may be disposed in the active area AA. The plurality of sub-pixels may be minimum units constituting the active area AA, and a light emitting element may be disposed in each of the plurality of sub-pixels. For example, an organic light emitting element including an anode, an organic light emitting layer, and a cathode may be disposed in each of the plurality of sub-pixels, but the present disclosure is not limited thereto. In addition, the circuits for driving the plurality of sub-pixels may include driving elements, lines and the like. For example, the circuits may include thin film transistors, a storage capacitor, gate lines, data lines, and the like, however, the present disclosure is not limited thereto.

A configuration of the plurality of sub-pixels will be described in more detail.

Referring to FIG. 2, each of the plurality of sub-pixels may include the first substrate 101, inorganic layers 110, a driving element 120, a planarization layer 102, a bank 103, a passivation layer 105, a light emitting element 150, an adhesive layer 130, and a second substrate 140.

The first substrate 101 may be a support substrate on which the plurality of pixels are disposed, and may be formed of transparent glass. When manufacturing a flexible display device, the first substrate 101 may be formed of a flexible organic material such as a plastic-based material. For example, the first substrate 101 may be formed of a material such as polyimide or the like.

A plurality of insulating inorganic layers 110 may be disposed on the first substrate 101. The insulating inorganic layers 110 may include a buffer layer 111, an insulating layer 112, and a gate insulating layer 113.

The buffer layer 111 may be a functional layer for protecting various electrodes and lines from impurities such as alkali ions or the like flowing out from the first substrate 101 or lower layers thereof. As illustrated in FIG. 2, the buffer layer 111 may have a multilayer structure formed of a first buffer layer 111a and a second buffer layer 111b. However, the present disclosure is not limited thereto. The buffer layer 111 may be formed of silicon oxide (SiOx), silicon nitride (SiNx), or a multilayer thereof.

The buffer layer 111 may retard diffusion of moisture and/or oxygen penetrating into the first substrate 101. In addition, the buffer layer 111 may include a multi-buffer and/or an active buffer. The active buffer may protect an active layer 121 formed of a semiconductor among components of the driving element 120 and may perform a function of blocking various types of defects introduced from the first substrate 101. The active buffer may be formed of amorphous silicon (a-Si) or the like.

The driving element 120 may be formed such that the active layer 121, the insulating layer 112, a gate electrode 123, the gate insulating layer 113, a source electrode (not shown), and a drain electrode 122 are sequentially disposed. The driving element 120 may be electrically coupled to the light emitting element 150 via a connection electrode 124 to transmit a current or signal to the light emitting element 150.

The active layer 121 may be disposed on the buffer layer 111. The active layer 121 may be formed of polysilicon (p-Si). In some embodiments, the active layer 121 may include a predetermined region that is doped with impurities. In other embodiments, the active layer 121 may be formed of amorphous silicon (a-Si) or may be formed of various organic semiconductor materials such as pentacene and the like. In yet further embodiments, the active layer 121 may be formed of an oxide semiconductor.

The insulating layer 112 may be disposed on the active layer 121. The insulating layer 112 may be formed of an insulating inorganic material such as silicon oxide (SiOx) or silicon nitride (SiNx), and may also be formed of an insulating organic material or the like.

The gate electrode 123 may be disposed on the insulating layer 112. The gate electrode 123 may be formed of various conductive materials including, but not limited to, magnesium (Mg), aluminum (Al), nickel (Ni), chromium (Cr), molybdenum (Mo), tungsten (W), gold (Au), or an alloy thereof.

The gate insulating layer 113 may be disposed on the gate electrode 123. The gate insulating layer 113 may be formed of an insulating material, including but not limited to, silicon oxide (SiOx) or silicon nitride (SiNx). The gate insulating layer 113 may also be formed of an insulating organic material or the like.

Contact holes for electrically coupling the source electrode and the drain electrode 122 with the active layer 121 may be formed in the insulating layer 112 and the gate insulating layer 113. The source electrode and the drain electrode 122 may be formed on the gate insulating layer 113 in a single-layer or multilayer structure of an electrode material. In some embodiments, an additional passivation layer formed of an insulating inorganic material may be formed to cover the source electrode and the drain electrode 122.

Although not illustrated in FIG. 2, a color filter may be further disposed on the gate insulating layer 113. The color filter may be disposed so as to correspond to an emission area where the light emitting element 150 is disposed. In this manner, when the color filter is disposed on the gate insulating layer 113, light emission of the display device in a bottom emission method may be more effectively performed.

The planarization layer 102 may be disposed on the driving element 120. In some embodiments, the planarization layer 102 may be formed of a single layer. In other embodiments, for example as illustrated in FIG. 2, the planarization layer 102 may have a multilayer structure composed of at least two layers including a first planarization layer 102a and a second planarization layer 102b. The first planarization layer 102a may be disposed to cover the driving element 120 in such a manner that portions of the source electrode and the drain electrode 122 of the driving element 120 are exposed. In some embodiments, the planarization layer 102 may extend to the non-active area NA. In some embodiments, the connection electrode 124 for electrically coupling the driving element 120 and the light emitting element 150 may be disposed on the first planarization layer 102a. In addition, although not illustrated in FIG. 2, various metal layers serving as electric lines/electrodes such as data lines and signal lines may be disposed on the first planarization layer 102a. In addition, the second planarization layer 102b may be disposed on the first planarization layer 102a and the connection electrode 124.

In some embodiments, in the display device 100, the planarization layer 102 may be formed of two layers due to an increase of various signal lines as the display device 100 has a higher resolution. Accordingly, an additional layer may be formed since it may be difficult to place all the lines on one layer while securing a minimum distance therebetween. As such, the additional layer, for example, the second planarization layer 102b, may generate a margin, and, thus, an electric line/electrode arrangement design may be further facilitated. In addition, when a dielectric material is used for the planarization layer 102 formed of multiple layers, the planarization layer 102 may also be used for forming capacitance between metal layers.

The second planarization layer 102b may be formed to expose a portion of the connection electrode 124. Moreover, the drain electrode 122 of the driving element 120 and an anode 151 of the light emitting element 150 may be electrically coupled via the connection electrode 124.

The light emitting element 150 may be configured by sequentially disposing the anode 151, an organic layer 152, and a cathode 153. That is, the light emitting element 150 may be configured to include the anode 151 formed on the planarization layer 102, the organic layer 152 formed on the anode 151, and the cathode 153 formed on the organic layer 152. The organic layer 152 may further be configured by stacking a plurality of organic layers.

The anode 151 may be formed of a transparent conductive material, including but not limited to, indium tin oxide (ITO), indium zinc oxide (IZO), or indium gallium zinc oxide (IGZO). Although it has been described that the anode 151 is formed of a transparent conductive material, the present disclosure is not limited thereto. For example, where a display device that utilizes a top emission type, the second substrate may be formed of a transparent material, and a reflective layer formed of an opaque conductive material having high reflectivity, such as silver (Ag), aluminum (Al), gold (Au), molybdenum (Mo), tungsten (W), chromium (Cr), or an alloy thereof, may be added under the anode 151 such that light emitted from the organic layer 152 is reflected by the anode 151 and directed upward (i.e., in a direction of the cathode 153, which is positioned above the anode 151).

The bank 103 may be disposed on the planarization layer 102 in an area other than the emission area. For example, the bank 103 may have a bank hole exposing the anode 151 so as to correspond to the emission area. In some embodiments, the bank 103 may be formed of an insulating inorganic material, including but not limited to, silicon nitride (SiNx) or silicon oxide (SiOx). In other embodiments, the bank 103 may be formed of an organic insulating material, including, but not limited to, BCB, acrylic resin, or imide resin. Moreover, the bank 103 may be disposed to extend to the non-active area NA.

The organic layer 152 may be disposed on at least a portion of the anode 151 that is exposed by the bank 103. The organic layer 152 may include a light emitting layer, an electron injection layer, an electron transport layer, a hole transport layer, a hole injection layer, and the like. The organic layer 152 may extend to the non-active area NA.

The cathode 153 may be disposed on the organic layer 152. The cathode 153 may include one or more metallic materials such as gold (Au), silver (Ag), aluminum (Al), molybdenum (Mo), magnesium (Mg), palladium (Pd), and copper (Cu), or alloys of them. Alternatively, the cathode 153 may be configured by stacking a layer formed of a transparent conductive material such as indium tin oxide (ITO), indium zinc oxide (IZO), or indium gallium zinc oxide (IGZO), and a layer formed of a metallic material such as gold (Au), silver (Ag), aluminum (Al), molybdenum (Mo), magnesium (Mg), palladium (Pd), or copper (Cu), or an alloy thereof, but the present disclosure is not limited thereto. Meanwhile, in the case of the top emission method, the cathode 153 may include a transparent conductive material. For example, the cathode 153 may be formed of indium tin oxide (ITO), indium zinc oxide (IZO), or indium gallium zinc oxide (IGZO). The cathode 153 may extend to the non-active area NA. The cathode 153 may be spaced apart from an end portion of the bank 103 by a predetermined distance and come into contact with a portion of an upper surface of the bank 103.

A capping layer 104 may be disposed on the light emitting element 150. The capping layer 104 may be formed of a material having a high refractive index and high light absorption in order to reduce diffused reflection of external light. The capping layer 104 may be an organic material layer formed of an organic material. In some embodiments, the capping layer 104 may be omitted.

The passivation layer 105 may be disposed on the capping layer 104. The passivation layer 105 may provide protection to the light emitting element 150 from external foreign materials, impacts, penetration of moisture and oxygen, and the like. The passivation layer 105 may be formed of an inorganic material. For example, the passivation layer 105 may be formed of an inorganic material such as silicon oxide (SiOx) or silicon nitride (SiNx). In some embodiments, the passivation layer 105 may be omitted.

The adhesive layer 130 may be disposed on the passivation layer 105. The adhesive layer 130 may bond the first substrate 101 and the second substrate 140 to each other. In some embodiments, the adhesive layer 130 is formed of resin, including but not limited to, epoxy, phenol, amino, unsaturated polyester, polyimide, silicone, acryl, vinyl and olefin. The adhesive layer 130 may be bonded via a high-energy curing method such as heat, ultraviolet rays, or laser, or may be bonded by a method of applying physical pressure using a pressure sensitive adhesive (PSA).

The second substrate 140 may be disposed on the adhesive layer 130. The second substrate 140 may have a size smaller than that of the first substrate 101. For example, an end portion of the second substrate 140 may be located inside the first substrate 101. Moreover, the second substrate 140 may have a coefficient of thermal expansion different from that of the first substrate 101. As such, the coefficient of thermal expansion thereof may be implemented to be equal, or similar, to that of the first substrate 101. The difference in coefficient of thermal expansion may thus prevent warpage. Accordingly, the second substrate 140 may be formed of an alloy of iron and nickel having a low coefficient of thermal expansion. The second substrate 140 may have a form of a foil or a metal thin film. The second substrate 140 may be thin and have a thickness that is equal to or greater than 50 μm and equal to or less than 500 μm. In some embodiments, the second substrate 140 may be manufactured to have a thickness of 100 μm which may result in a volume that may be reduced thereby minimizing warpage of the first substrate 101 that is caused by the second substrate 140. The second substrate 140 may also be referred to as a metal substrate.

A polarizing plate 190 may be disposed under the first substrate 101. The polarizing plate 190 may selectively transmit light to reduce reflection of external light incident on the first substrate 101. For example, in the display device 100, various metallic materials that are applied to semiconductor elements, lines, light emitting elements and the like may be disposed on the first substrate 101. Accordingly, external light incident onto the first substrate 101 may be reflected from the metallic materials such that visibility of the display may be reduced. In some embodiments, exterior visibility of the display device 100 may be increased by disposing the polarizing plate 190 that prevents reflection of external light, under the first substrate 101. In other embodiments, the polarizing plate 190 may be omitted. For example, a display device according to another embodiment may be a top emission display device. In case of the top emission display device, the polarizing plate 190 may be disposed on the top of the second substrate 140 rather than on the bottom of the first substrate 101.

Referring to FIG. 1, the non-active area NA may be an area in which an image is not displayed. Although FIG. 1 illustrates that the non-active area NA surrounds the active area AA having a quadrangular shape, shapes and arrangements of the active area AA and the non-active area NA are not so limited to the example illustrated in FIG. 1. For example, the active area AA and the non-active area NA may have shapes suitable for a design of an electronic apparatus in which the display device 100 is mounted. For example, a shape of the active area AA may be a pentagonal shape, a hexagonal shape, a circular shape, or an elliptical shape.

In the non-active area NA, various lines and circuits for driving the light emitting elements of the active area AA may be disposed. For example, in the non-active area NA, driver ICs such as a gate driver IC and a data driver IC, or link lines for transmitting signals to the plurality of sub-pixels and circuits of the active area AA may be disposed, however, the present disclosure is not limited thereto.

The display device 100 may include various additional elements for generating various signals or driving the plurality of pixels arranged in the active area AA. The additional elements for driving the pixels may include an inverter circuit, a multiplexer, an electrostatic discharge (ESD) circuit, and the like. The display device 100 may also include additional elements related to functions other than pixel driving. For example, the display device 100 may include additional elements that provide a touch sensing function, a user authentication function (e.g., fingerprint recognition), a multi-level pressure sensing function, a tactile feedback function, and the like. The aforementioned additional elements may be located in the non-active area NA and/or in an external circuit connected to a connection interface.

The flexible films 160 may be films in which various parts are disposed on flexible base films. In some embodiments, the flexible film 160 may be a film for supplying signals to the plurality of sub-pixels and circuits of the active area AA, and may be electrically coupled to the first substrate 101. The flexible film 160 may be disposed on one end of the non-active area NA in the first substrate 101 and supply power voltages, data voltages, and the like to the plurality of sub-pixels and circuits of the active area AA. The display device 100 may include any suitable number of flexible films 160 according to a particular design.

Meanwhile, the driver ICs such as a gate driver IC and a data driver IC may be disposed on the flexible film 160. The driver IC may be a component that processes data for displaying an image and a driving signal for processing the data. The driver IC may be disposed in a method such as a chip on glass (COG) method, a chip on film (COF) method, or a tape carrier package (TCP) method depending on a mounting method.

The printed circuit board 170 may be disposed on one end of the flexible films 160 and connected to the flexible films 160. The printed circuit board 170 may be a component that supplies signals to the driver ICs. The printed circuit board 170 may supply various signals such as driving signals and data signals to the driver ICs. In some embodiments, a data driver for generating data signals may be mounted on the printed circuit board 170, and the generated data signals may be supplied to the plurality of sub-pixels and circuits of the first substrate 101 through the flexible films 160. The display device 100 may include any suitable number of printed circuit boards 170, which may vary according to a particular design, but the present disclosure is not limited thereto.

As described above, the display device 100 may be manufactured by bonding the first substrate 101 on which light emitting elements are disposed, and the second substrate 140 formed of the metal thin film and to which the adhesive layer 130 is attached. More specifically, the display device 100 may be manufactured by aligning and bonding other components constituting the first substrate 101 and the second substrate 140 and cutting the bonded first substrate 101 and second substrate 140 by model. Such a manufacturing process may allow for the introduction of moisture and oxygen through a side surface of an outer edge of the display device 100, which may cause defects in the light emitting element 150 and the like, and degrade reliability of the display device 100.

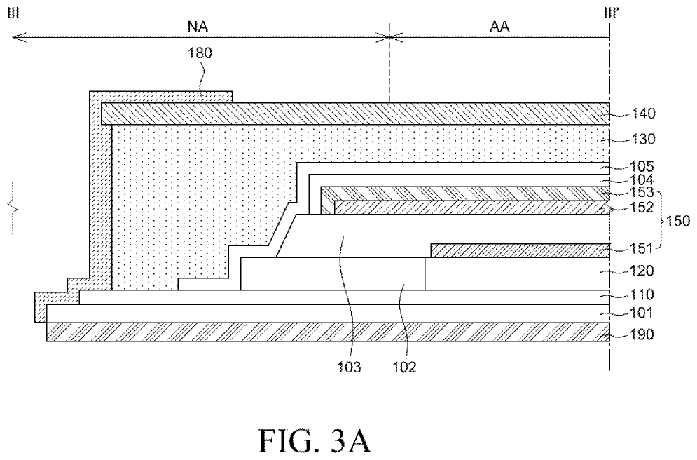

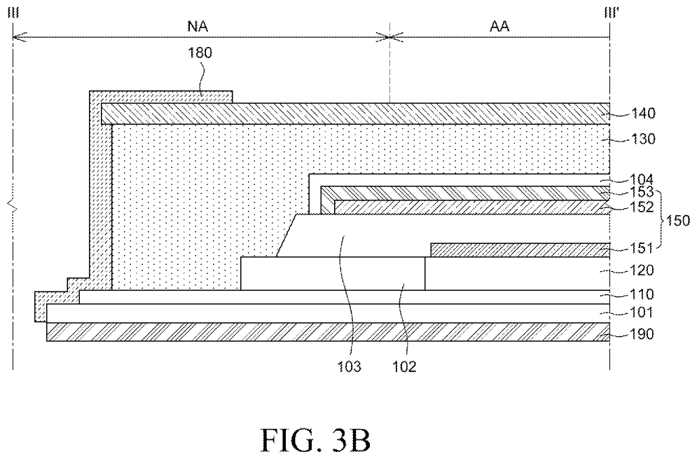

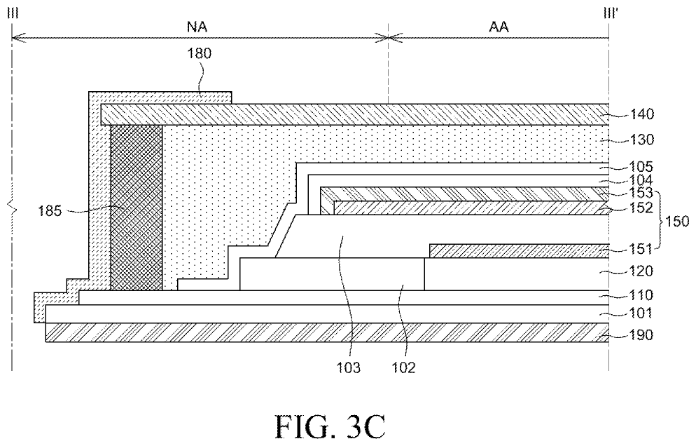

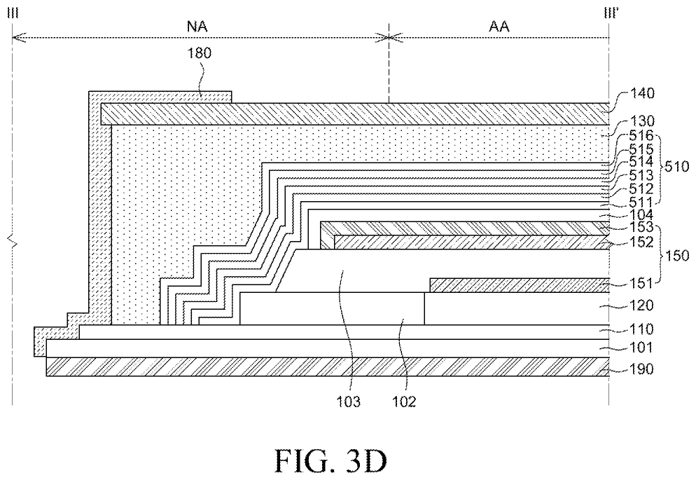

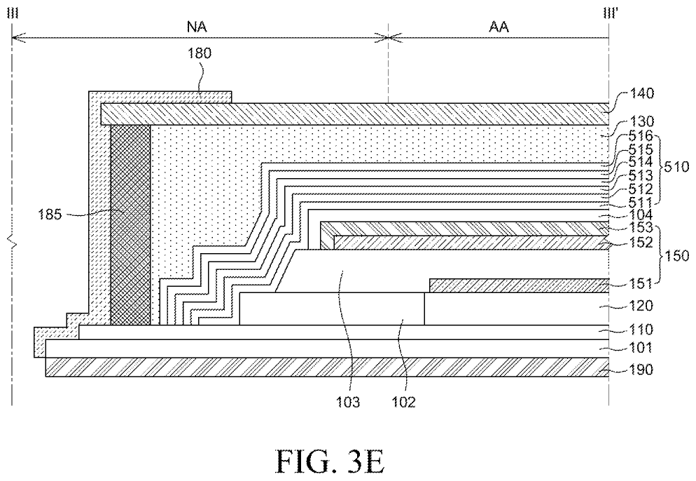

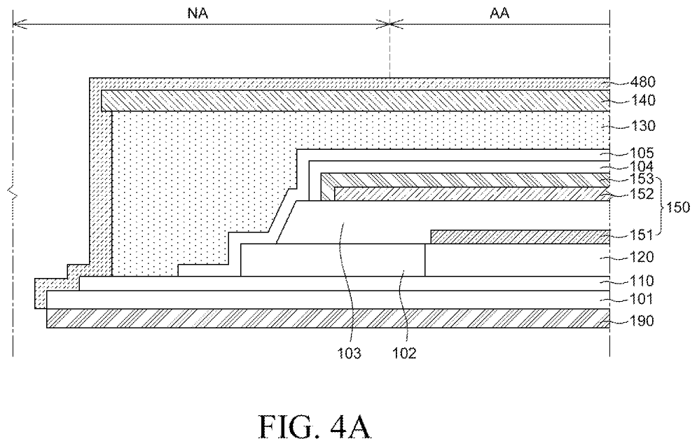

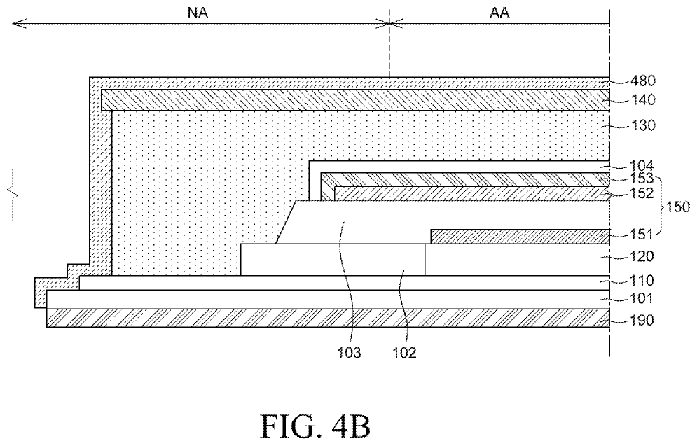

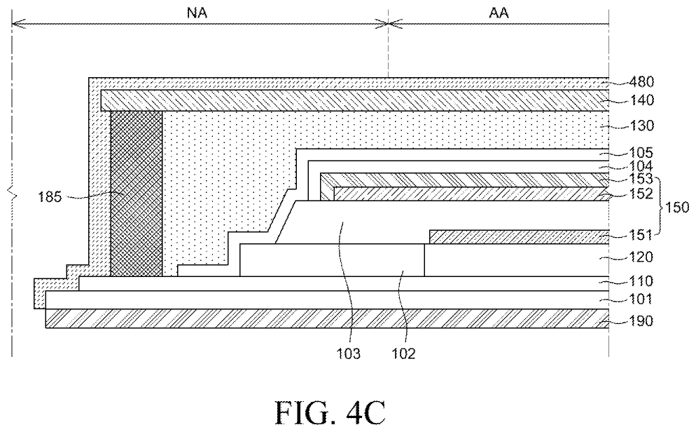

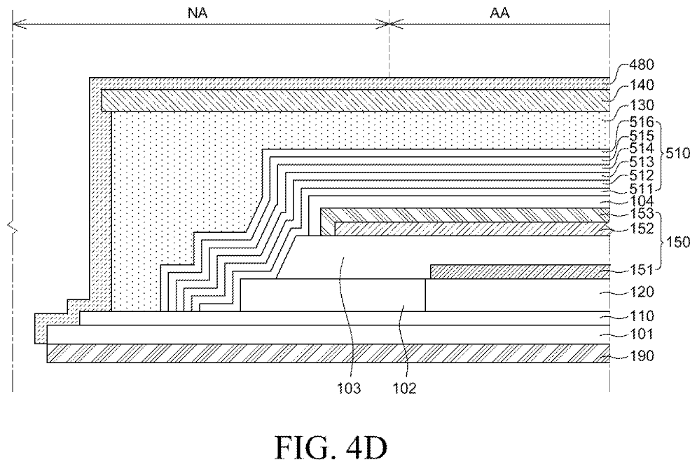

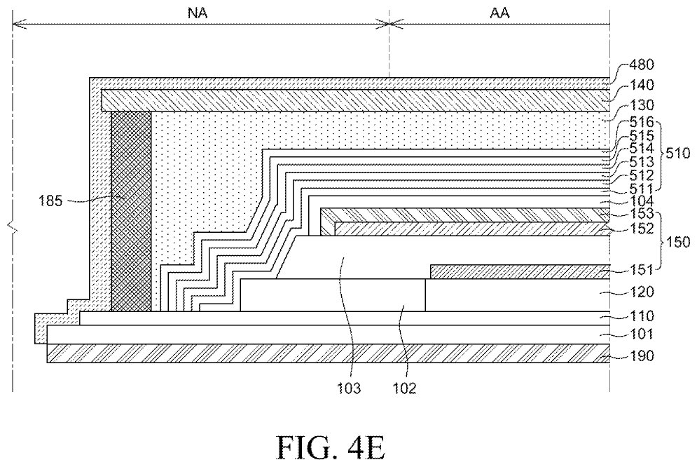

Accordingly, the display device 100 may further include the moisture barrier coating layer 180. The moisture barrier coating layer 180 may be disposed so as to cover an upper surface of the second substrate 140 of the display device 100 and cover a side surface of an end portion of the first substrate 101 along a side surface of the display device 100 thus aiding in the prevention of the introduction of moisture and oxygen penetrating from the side surface of the outer edge of the display device 100. The moisture barrier coating layer 180 described above will be explained in more detail with reference to FIG. 3A to FIG. 3E and FIG. 4A to FIG. 4E below.

FIGS. 3A, 3C and FIGS. 4A, 4C illustrate the display device 100 in a case where the passivation layer 105 is disposed over the light emitting element 150 and FIGS. 3B, 3D, 3E and FIGS. 4B, 4D, 4E illustrate the display device 100 in a case where the passivation layer 105 is not disposed over the light emitting element 150.

FIG. 3A to FIG. 3E and FIG. 4B to FIG. 4E schematically illustrate the driving element 120 in the active area AA for convenience of description. The driving element 120 may include various components below the light emitting element 150. In addition, the non-active area NA may also include various components, and is schematically illustrated for convenience of description.

Referring to FIG. 3A, in the display device 100, the first substrate 101, the inorganic layer 110, the planarization layer 102, the bank 103, the organic layer 152, the cathode 153, the capping layer 104, the passivation layer 105, the adhesive layer 130, and the second substrate 140 may be sequentially stacked and disposed.

An end portion of the inorganic layer 110 on the first substrate 101 may be located between the end portion of the first substrate 101 and the end portion of the second substrate 140. In some embodiments, as illustrated in FIG. 3A to FIG. 4B, the end portion of the inorganic layer 110 may be located outside an end portion of the adhesive layer 130. However, the present disclosure need not be so limited and, in other embodiments, the end portion of the inorganic layer 110 may be located inside the adhesive layer 130.

In some embodiments, end portions of the planarization layer 102, the bank 103, the organic layer 152 and the cathode 153 of the light emitting element 150, and the capping layer 104, which are on the inorganic layer 110 may be located inside the first substrate 101 and the second substrate 140 in the non-active area NA, and the passivation layer 105 may be disposed to cover the end portions of the planarization layer 102, the bank 103, the organic layer 152 and the cathode 153 of the light emitting element 150, and the capping layer 104. The end portion of the adhesive layer 130 on the passivation layer 105 may be located between the end portion of the inorganic layer 110 and the end portion of the second substrate 140, and an end portion of the passivation layer 105 may be located inside the end portion of the adhesive layer 130. Accordingly, at a side surface of the display device 100 according to an exemplary embodiment of the present disclosure, the end portion of the first substrate 101, the end portion of the inorganic layer 110, the end portion of the adhesive layer 130, and the end portion of the second substrate 140 may be disposed.

The moisture barrier coating layer 180 may be disposed to cover the side surface of the end portion of the first substrate 101 along the side surface of the display device 100 while covering a portion of the upper surface of the second substrate 140 in the non-active area NA. The moisture barrier coating layer 180 may be disposed so as to correspond to only the non-active area NA. In some embodiments, the moisture barrier coating layer 180 may be in contact with the end portion of the first substrate 101, the end portion of the second substrate 140, the end portion of the inorganic layer 110, and the end portion of the adhesive layer 130. Moreover, an end portion of the moisture barrier coating layer 180 on the upper surface of the second substrate 140, may be located between the end portion of the passivation layer 105 and an end portion of the planarization layer 102.

The moisture barrier coating layer 180 may be formed by coating fluorine in a plasma method. For example, the moisture barrier coating layer 180 may be deposited on the side surface of the end portion of the first substrate 101 along the side surface of the display device while covering a portion of the upper surface of the second substrate 140 of the display device 100 in a CF₂ polymer state in a vacuum chamber by activating carbon tetrafluoride (CF₄) gas with plasma. Accordingly, hydrophobicity of the display device 100 may be enhanced. Thus, the moisture barrier coating layer 180 may prevent penetration of moisture and oxygen through the side surface of the display device 100. Meanwhile, the display device of FIG. 3B is a display device in which the passivation layer 105 for protecting the light emitting element 150 against external foreign materials, impacts, and penetration of moisture and oxygen is omitted from the display device 100 of FIG. 3A.

Referring to FIG. 3B, in the non-active area NA of the display device, the inorganic layer 110, the planarization layer 102, the bank 103, the organic layer 152, the cathode 153, the adhesive layer 130, and the second substrate 140 may be disposed on the first substrate 101 and extend from the active area AA. The moisture barrier coating layer 180 may be disposed to cover the side surface of the end portion of the first substrate 101 along the side surface of the display device 100 while covering a portion of the upper surface of the second substrate 140 in the non-active area NA.

Moreover, in the display device of FIG. 3C, a dam 185 is added to minimize moisture and oxygen infiltration through the side portion of the display device 100 of FIG. 3A.

Referring to FIG. 3C, the dam 185 may be disposed between the first substrate 101 and the second substrate 140 in the non-active area NA. For example, the dam 185 may be any one of an epoxy-based or acrylic-based sealing materials to which a thermal curing accelerator and a photoinitiator are added.

For example, the dam 185 is formed to surround the active area AA in a plan view, and may bond the first substrate 101 and the second substrate 140 with the adhesive layer 130 to seal them. Accordingly, the dam 185 may be disposed in an area where the first substrate 101 and the second substrate 140 overlap each other. The dam 185 may block the introduction of moisture and oxygen that may permeate between the first substrate 101 and the second substrate 140 through a side surface of the display device 100.

Moreover, the display device of FIG. 3D has a thin film encapsulation layer 510 added compared to the display device 100 of FIG. 3A.

Referring to FIG. 3D, the capping layer 104 may be disposed on the light emitting element 150, which is disposed on the first substrate 101, and the thin film encapsulation layer 510 may be disposed on the capping layer 104. The thin film encapsulation layer 510 may aid in protecting the light emitting element 150 from external foreign materials, impacts, penetration of moisture and oxygen, and the like. The thin film encapsulation layer 510 may include a plurality of inorganic layers 511, 512, 514, and 515 and a plurality of organic layers 513 and 516. In some embodiments, the thin film encapsulation layer 510 may be configured by stacking a first inorganic layer 511, a second inorganic layer 512, a first organic layer 513, a third inorganic layer 514, a fourth inorganic layer 515, and a second organic layer 516 in sequence.

The first inorganic layer 511, the second inorganic layer 512, the third inorganic layer 514, and the fourth inorganic layer 515 may be formed of an inorganic material such as silicon oxide (SiOx) or silicon nitride (SiNx). The first inorganic layer 511 and the third inorganic layer 514 may be formed via an atomic layer deposition (ALD) method, which can be performed without a seam, and, thereby, provide good side step coverage. However, the present disclosure is not limited thereto. The first organic layer 513 and the second organic layer 516 may be formed of an organic material, for example, olefin-based polyethylene.

In the display device of FIG. 3D, the thin film encapsulation layer 510 composed of a plurality of inorganic films 511, 512, 514, and 515 and a plurality of organic films 513 and 516 is disposed on the light emitting element 150. By doing so, the light emitting element 150 can be effectively protected from moisture and oxygen that may have penetrated.

Moreover, the display device of FIG. 3E has a dam 185 and a thin film encapsulation layer 510 added compared to the display device 100 of FIG. 3A. Therefore, a detailed description of the display device of FIG. 3E may refer to the description of FIGS. 3C and 3D described above.

Referring to FIG. 3E, the dam 185 may be disposed between the first substrate 101 and the second substrate 140 in the non-active area NA. For example, the dam 185 is formed to surround the active area AA in a plan view, and may bond the first substrate 101 and the second substrate 140 with the adhesive layer 130 to seal them. Accordingly, the dam 185 may be disposed in an area where the first substrate 101 and the second substrate 140 overlap each other.

Moreover, the capping layer 104 may be disposed on the light emitting element 150, and the thin film encapsulation layer 510 may be disposed on the capping layer 104. The thin film encapsulation layer 510 may include a plurality of inorganic layers 511, 512, 514, and 515 and a plurality of organic layers 513 and 516. In some embodiments, the thin film encapsulation layer 510 may be configured by stacking a first inorganic layer 511, a second inorganic layer 512, a first organic layer 513, a third inorganic layer 514, a fourth inorganic layer 515, and a second organic layer 516 in sequence.

By disposing the moisture barrier coating layer 180 that covers the side surface of the end portion of the first substrate 101 along the side surface of the display device 100 while covering the upper surface of the second substrate 140 in the non-active area NA, penetration of moisture and oxygen into an interior of the display device 100 may be minimized and reliability of the display device 100 may be improved. In some embodiments, the moisture barrier coating layer 180 may be positioned so as to extend to the active area AA.

Referring to FIGS. 4A to 4E, a moisture barrier coating layer 480 may be disposed on the side surface of the end portion of the first substrate 101 along the side surface of the display device while covering an entirety of the upper surface of the second substrate 140. For example, the moisture barrier coating layer 480 may be positioned so as to correspond to an entire surface of the active area AA and the non-active area NA of the display device. Accordingly, the moisture barrier coating layer 480 may be disposed such that it covers all of an upper surface and both side surfaces of the first substrate 101 except for a lower portion of the display device 100.

Hereinafter, a display device according to another embodiment, will be described.

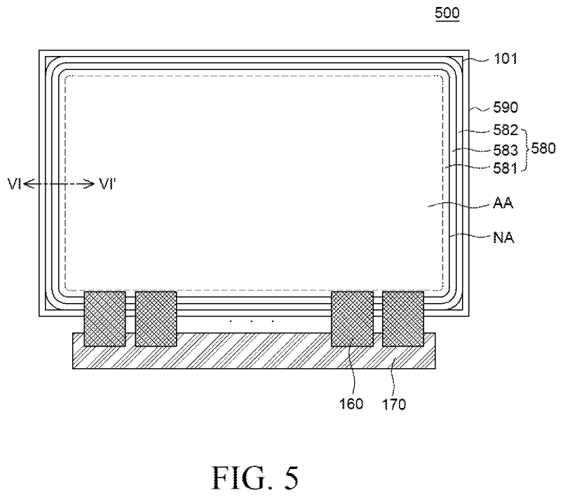

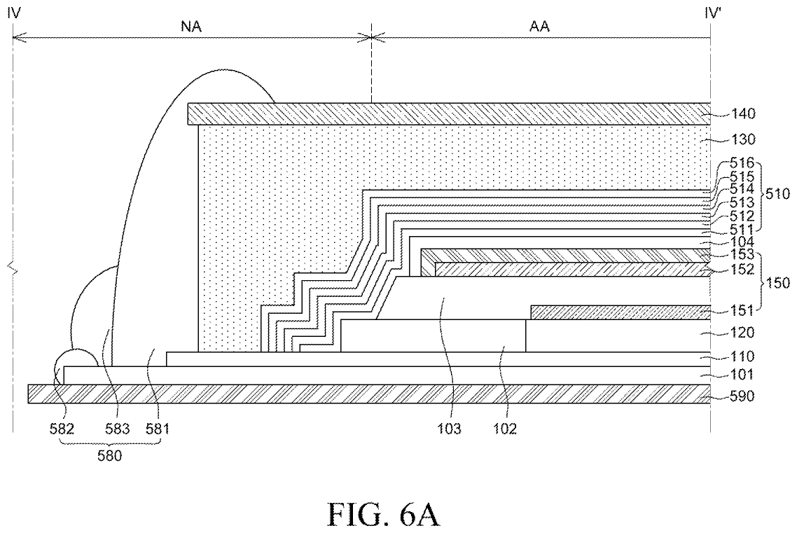

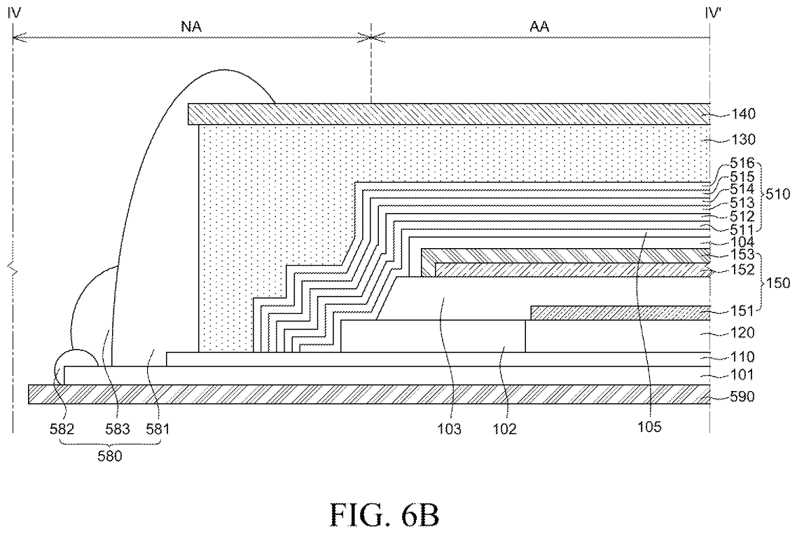

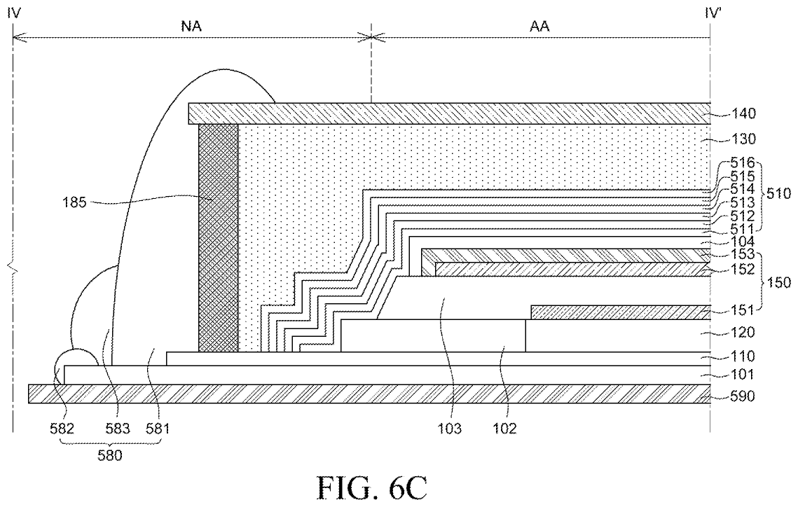

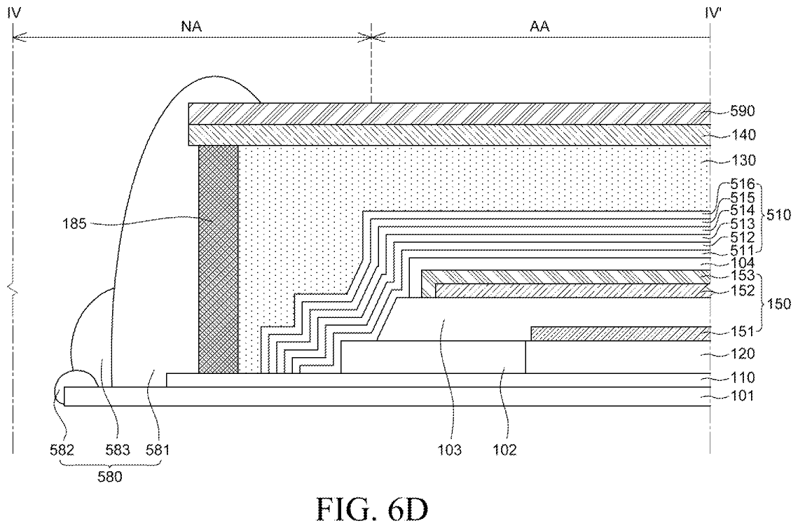

The display device 500, as illustrated in FIG. 5 and FIGS. 6A to 6D, may be substantially identical to the display device 100 illustrated in FIGS. 1, 2, FIGS. 3A to 3E and FIGS. 4A to 4E. As such, duplicate descriptions thereof will be omitted. The display device 500, may further include a side sealing part 580.

FIGS. 6A to 6D schematically illustrate the driving element 120 in the active area AA for convenience of description. The driving element 120 may include various components below the light emitting element 150. In addition, the non-active area NA may also include various components, and is schematically illustrated for convenience of description.

Referring to FIG. 5 and FIGS. 6A to 6D, the display device 500 may include the first substrate 101, the inorganic layers 110, the driving element 120, the planarization layer 102, the bank 103, the light emitting element 150, the capping layer 104, the thin film encapsulation layer 510, the adhesive layer 130, the second substrate 140, the side sealing part 580, and the polarizing plate 590. The polarizing plate 590 may be disposed under the first substrate 101. The polarizing plate 590 may selectively transmit light to reduce reflection of external light incident onto the first substrate 101. The polarizing plate 590 may have a size greater than that of the first substrate 101.

Referring to FIGS. 6A to 6D, an end portion of the polarizing plate 590 may be located outside the end portion of the first substrate 101. Accordingly, some components of the side sealing part 580 may be disposed on the side surface of the end portion of the first substrate 101 and on a portion of an upper portion of the polarizing plate 590. The capping layer 104 may be disposed on the light emitting element 150, which is disposed on the first substrate 101, and the thin film encapsulation layer 510 may be disposed on the capping layer 104. The thin film encapsulation layer 510 may aid in protecting the light emitting element 150 from external foreign materials, impacts, penetration of moisture and oxygen, and the like. The thin film encapsulation layer 510 may include a plurality of inorganic layers 511, 512, 514, and 515 and a plurality of organic layers 513 and 516. In some embodiments, the thin film encapsulation layer 510 may be configured by stacking a first inorganic layer 511, a second inorganic layer 512, a first organic layer 513, a third inorganic layer 514, a fourth inorganic layer 515, and a second organic layer 516 in sequence.

The first inorganic layer 511, the second inorganic layer 512, the third inorganic layer 514, and the fourth inorganic layer 515 may be formed of an inorganic material such as silicon oxide (SiOx) or silicon nitride (SiNx). The first inorganic layer 511 and the third inorganic layer 514 may be formed via an atomic layer deposition (ALD) method, which can be performed without a seam, and, thereby, provide good side step coverage. However, the present disclosure is not limited thereto. The first organic layer 513 and the second organic layer 516 may be formed of an organic material, for example, olefin-based polyethylene.

Referring to FIG. 6B, the capping layer 104 may be disposed on the light emitting element 150, the passivation layer 105, formed of an insulating inorganic material, may be disposed on the capping layer 104, and the thin film encapsulation layer 510 may be disposed on the passivation layer 105. In other words, two inorganic layers including the passivation layer 105 and the first inorganic layer 511 may be disposed on the capping layer 104.

Referring to FIG. 6C, the dam 185 may be disposed between the first substrate 101 and the second substrate 140 in the non-active area NA. For example, the dam 185 may be formed to surround the active area AA in a plan view, and may bond the first substrate 101 and the second substrate 140 with the adhesive layer 130 to seal them. Accordingly, the dam 185 may be disposed in an area where the first substrate 101 and the second substrate 140 overlap each other. The second substrate 140 may have a coefficient of thermal expansion different from that of the first substrate 101. As such, the coefficient of thermal expansion thereof may be implemented to be equal, or similar, to that of the first substrate 101. The difference in coefficient of thermal expansion may thus prevent warpage. Accordingly, the second substrate 140 may be formed of an alloy of iron and nickel having a low coefficient of thermal expansion. The second substrate 140 may have a form of a foil or a metal thin film. The second substrate 140 may also be referred to as a metal substrate. However, it is not limited to this, and the second substrate 140 may also be made of glass or transparent plastic.

Alternatively, in FIG. 6C, only the dam 185 may be disposed without the thin film encapsulation layer 150.

Moreover, referring to FIG. 6D, a display device according to another embodiment may be the top emission display device. In the case of the top emission display device, the polarizing plate 590 may be disposed on the top of the second substrate 140 rather than on the bottom of the first substrate 101. In this case, the second substrate 140 may be made of glass or transparent plastic.

The display device 500 includes the thin film encapsulation layer 510 which is formed by disposing the organic layers 513 and 516 on the plurality of inorganic layers 511, 512, 514, and 515, while forming a protective layer composed of a plurality of layers to protect the light emitting element 150 with plurality of inorganic layers 511, 512, 514, and 515, which may protect the light emitting element 150 more effectively from oxygen and foreign materials.

The side sealing part 580 may be disposed in the non-active area NA, and may be positioned so as to cover the side surface of the end portion of the first substrate 101 along a side surface of an outer portion of the display device 500 while covering a portion of the upper surface of the second substrate 140. The side sealing part 580 may include a first side sealing portion 581, a second side sealing portion 582, and a third side sealing portion 583.

The first side sealing portion 581 may be disposed between the second substrate 140 and the first substrate 101. The first side sealing portion 581 may be positioned so as to cover at least a portion of the upper surface of the first substrate 101 along a side surface of the display device between the first substrate 101 and the second substrate 140 as well as a portion of the upper surface of the second substrate 140. The first side sealing portion 581 may be positioned such that it aids in the prevention of penetration of moisture, oxygen, or foreign materials into an inside of the display device 500 and, thereby, blocking damage to the light emitting element 150. The first side sealing portion 581 may be formed of a sealing material, for example, a frit sealing material. The frit sealing material constituting the first side sealing portion 581 may be a thermal curing agent or a laser curing agent. In some embodiments, the thermal curing agent may be a UV laser curing agent. The first side sealing portion 581 may be disposed such that a side surface thereof between the upper surface of the second substrate 140 and the first substrate 101 forms a convex curved shape.

The second side sealing portion 582 may be disposed between the first substrate 101 and the polarizing plate 590. The second side sealing portion 582 may be disposed to cover the side surface of the end portion of the first substrate 101 and at least a portion of an upper surface of the polarizing plate 590 as well as a portion of the upper surface of the first substrate 101. The second side sealing portion 582 may be disposed to prevent cracks of the first substrate 101. The second side sealing portion 582 may be formed of a material different from that of the first side sealing portion 581. In some embodiments, the second side sealing portion 582 may be formed of epoxy or acrylic-based resin having insulating properties and may be capable of being applied thinly. The epoxy or acrylic-based resin constituting the second side sealing portion 582 may be a UV laser curing agent. The second side sealing portion 582 may be disposed so that the side surface of the first substrate 101 may have a round corner shape or a convex curved shape.

The third side sealing portion 583 may be disposed between the first side sealing portion 581 and the second side sealing portion 582. The third side sealing portion 583 may be positioned so as to cover a space between the first side sealing portion 581 and the second side sealing portion 582 and contact the first side sealing portion 581 and the second side sealing portion 582. The third side sealing portion 583 may further strengthen adhesiveness between the first side sealing portion 581 and the second side sealing portion 582. In addition, the third side sealing portion 583 may cover the space between the first side sealing portion 581 and the second side sealing portion 582 such that introduction of moisture and oxygen into the inside of the display device 500 may be minimized. The third side sealing portion 583 may be formed of epoxy or acrylic-based resin. The epoxy or acrylic-based resin constituting the third side sealing portion 583 may be a UV laser curing agent.

The display device 500 may be configured such that external moisture and oxygen may be prevented from penetrating the side sealing part 580. Moreover, in instances where the moisture and oxygen may penetrate the display device 500, the light emitting element 150 may be effectively protected from the moisture and oxygen by disposing the thin film encapsulation layer 510 including the plurality of inorganic layers 511, 512, 514 and 515 and the plurality of organic layers 513 and 516 on the light emitting element 150.

As described above, the second substrate 140 of the display device 500 may be formed of a metal thin film. Furthermore, a protrusion or a bump may be formed at the end portion of the second substrate 140 due to expansion of the second substrate 140 during a driving operation at a high temperature. After bonding the first substrate 101 and the second substrate 140, and, when they are electrically coupled with the flexible films 160 coupling the first substrate 101 and the printed circuit board 170, the flexible films 160 may contact the end portion of the second substrate 140. In a conventional display device, there is commonly a defect in which the flexible film is dented and thus, lines within the flexible film are damaged. However, in the display device 500, the side sealing part 580 is formed to have a convex curved shape that includes a corner portion of the end portion of each of the first substrate 101 and the second substrate 140 and has a rounded corner shape to aid in preventing the lines of the flexible film 160 from being dented and damaged. Hereinafter, a display device according to another embodiment will be described.

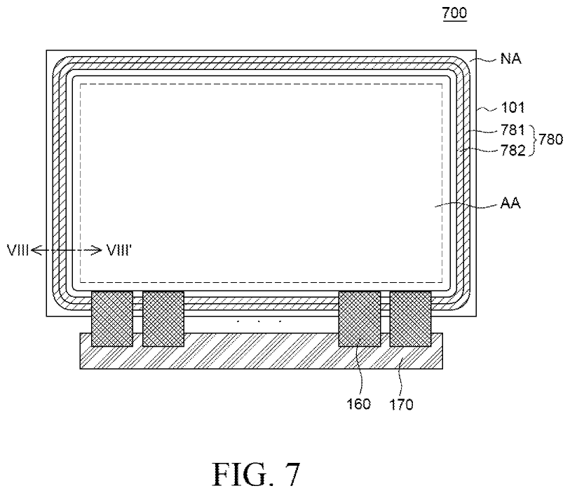

Display device 700, as illustrated in FIG. 7 to FIGS. 9A and 9B, is substantially identical to that of the display device 100 in FIG. 1 to FIGS. 3A, 3B, 3D, FIGS. 4A, 4B and 4D and further includes a dam part 780. As such, duplicate descriptions of the substantially identical configurations will be omitted.

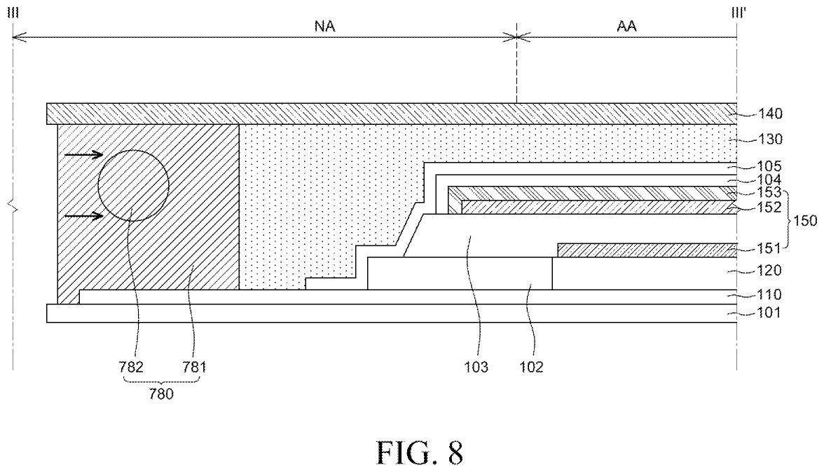

FIG. 8 schematically illustrates the driving element 120 in the active area AA for convenience of description. For example, the driving element 120 may include various components below the light emitting element 150. In addition, the non-active area NA may also include various components, and is schematically illustrated for convenience of description.

Referring to FIGS. 7 and 8, the display device 700 according to another example embodiment of the present disclosure may include the first substrate 101, the inorganic layers 110, the driving element 120, the planarization layer 102, the bank 103, the organic layer 152 and the cathode 153 of the light emitting element 150, the capping layer 104, the adhesive layer 130, the second substrate 140, and the dam part 780.

The first substrate 101, the inorganic layer 110, the driving element 120, the planarization layer 102, the bank 103, the organic layer 152 and the cathode 153 of the light emitting element 150, the capping layer 104, the adhesive layer 130, and the second substrate 140 may be disposed from the active area AA to the non-active area NA. In FIG. 1 to FIGS. 6A, 6B, 6C and 6D, it has been described that a size of the second substrate 140 may be smaller than that of the first substrate 101. However, the display device 700 is not limited to the example above, and the second substrate 140 may be formed to have the same, or substantially same, size as that of the first substrate 101 and may be formed of not only a thin metallic material but may also be formed of glass or transparent plastic. As described above, in instances where the second substrate 140 of the display device 700 is formed of a transparent material, the display device 700 may be a display device that utilizes the top emission method. In the case of a top emission display device, the polarizing plate 190 may be disposed above the second substrate 140 instead of being disposed below the first substrate 101.

The dam part 780 may be disposed between the first substrate 101 and the second substrate 140 in the non-active area NA. That is, the dam part 780 is formed to surround the active area AA in a plan view, and may bond the first substrate 101 and the second substrate 140 with the adhesive layer 130 to seal them. Accordingly, the dam part 780 may be disposed in an area where the first substrate 101 and the second substrate 140 overlap each other. The dam part 780 may block the introduction of moisture and oxygen that may permeate between the first substrate 101 and the second substrate 140 through a side surface of the display device 700.

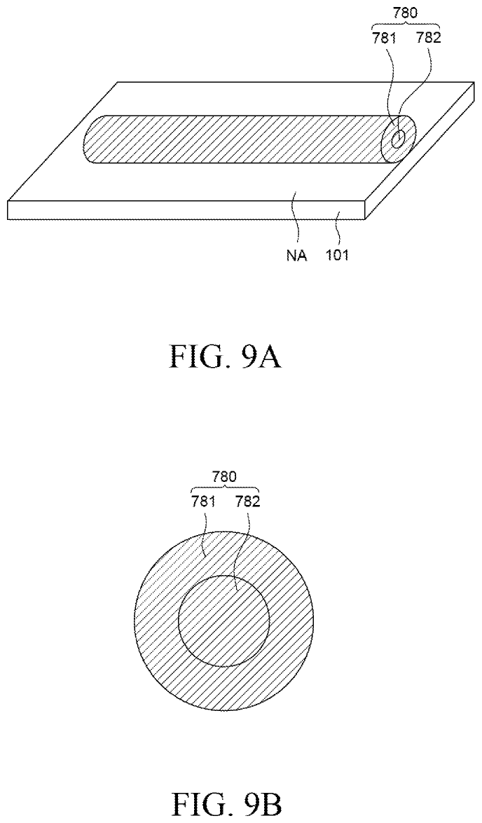

Referring to FIGS. 9A and 9B, the dam part 780 may include a base dam portion 781 and a moisture absorption layer 782 disposed in the base dam portion 781. The base dam portion 781 may be disposed to contact each of the first substrate 101 and the second substrate 140 and, as illustrated in FIGS. 9A and 9B, may be configured to surround the moisture absorption layer 782 disposed therein. The base dam portion 781 may be formed of any one of a thermal curing agent and an UV curing agent. For example, the base dam portion 781 may be any one of an epoxy-based or acrylic-based sealing materials to which a thermal curing accelerator and a photoinitiator are added. The base dam portion 781 may serve to block penetration of moisture and oxygen while reinforcing adhesiveness between the first substrate 101 and the second substrate 140.

Referring to FIG. 9A, the base dam portion 781 may be configured to have a cylindrical shape and disposed on the first substrate 101. However, the base dam portion 781 may have a quadrangular shape by positioning the second substrate 140 on the first substrate 101 coated with the base dam portion 781.

The moisture absorption layer 782 may be disposed within the base dam portion 781. As illustrated in FIG. 9A, the moisture absorption layer 782 may be disposed in a horizontal direction within the base dam portion 781 disposed on the first substrate 101. In some embodiments, as illustrated in FIGS. 9A and 9B, the moisture absorption layer 782 may have a circular shape in cross-section within the base dam portion 781. However, but the present disclosure is not limited thereto and the moisture absorption layer 782 may have any suitable shape such as a quadrangular shape or a polygonal shape within the base dam portion 781. In addition, although it is illustrated that only one moisture absorption layer 782 is disposed within the base dam portion 781, the present disclosure is not limited thereto, and a plurality of moisture absorption layers 782 may be disposed in the horizontal direction within the base dam portion 781. The moisture absorption layer 782 may be formed of a moisture adsorbent. The moisture absorption layer 782 may be formed of, for example, alkali metal oxide, silica, porous zeolite, or other organic or inorganic moisture absorbents. Examples of a moisture-reactive moisture absorbent may include one kind or a mixture of two or more kinds of metal powder such as alumina, a metal oxide, metal salts, or phosphorus pentoxide (P₂O₅). Examples of a physical adsorbent may include silica, zeolite, titania, zirconia, montmorillonite, and the like. Specific examples of the metal oxide include lithium oxide (Li₂O), sodium oxide (Na₂O), barium oxide (BaO), calcium oxide (CaO), or magnesium oxide (MgO). In addition, examples of the metal salts may include sulfates such as lithium sulfate (Li₂SO₄), sodium sulfate (Na₂SO₄), calcium sulfate (CaSO₄), magnesium sulfate (MgSO₄), cobalt sulfate (CoSO₄), gallium sulfate (Ga₂(SO₄)₃), titanium sulfate (Ti(SO₄)₂), or nickel sulfate (NiSO₄); metal halides such as calcium chloride (CaCl₂)), magnesium chloride (MgCl₂), strontium chloride (SrCl₂), yttrium chloride (YCl₃), copper chloride (CuCl₂), cesium fluoride (CsF), tantalum fluoride (TaF₅), niobium fluoride (NbF₅), lithium bromide (LiBr), calcium bromide (CaBr₂), cesium bromide (CeBr₃), selenium bromide (SeBr₄), vanadium bromide (VBr₃), magnesium bromide (MgBr₂), barium iodide (BaI₂) or magnesium iodide (MgI₂); or metal chlorates such as barium perchlorate (Ba(ClO₄)₂) or magnesium perchlorate (Mg(ClO₄)₂). However, the present disclosure is not limited thereto. The moisture absorption layer 782 may be disposed within the base dam portion 781 and form at least a portion of an exterior shape of the dam part 780 to retard penetration of moisture and oxygen penetrated from the outside.

In a dam forming apparatus having a first dispenser for forming the base dam portion 781 and a second dispenser for forming the moisture absorption layer 782, the moisture adsorbent constituting the moisture absorption layer 782 and the sealing material constituting the base dam portion 781 may be simultaneously discharged through a first discharge nozzle of the first dispenser and a second discharge nozzle of the second dispenser, whereby the dam part 780 may be formed such that the moisture absorption layer 782 is located inside the base dam portion 781. Accordingly, even when the moisture absorption layer 782 is formed within the base dam portion 781, a separate process for forming the moisture absorption layer 782 may not be added.

As described above, by positioning the dam part 780, which includes the moisture absorption layer 782, between the first substrate 101 and the second substrate 140, adhesiveness between the first substrate 101 and the second substrate 140 of the display device 700 may be improved. Moreover, such a configuration may allow for improved blocking penetration of moisture and oxygen from the outside, so that a lifespan and reliability of the display device 700 may be improved.

Example embodiments of the present disclosure may be described as follows.

In one or more example embodiments, a display device may include a first substrate and a second substrate. The first substrate may include an active area in which a light emitting element is disposed and a non-active area surrounding the active area. The second substrate may be disposed on the first substrate. The display device may further include a coating layer disposed to contact a portion of the first substrate, a portion of the second substrate, and a portion of the adhesive layer.

In some example embodiments, the coating layer may be disposed on the end portion of the first substrate, the end portion of the second substrate, and the end portion of the adhesive layer. The coating layer may cover at least a portion of an upper surface of the second substrate corresponding to the non-active area.

In some example embodiments, the coating layer may cover an entire surface of the second substrate corresponding to the active area and the non-active area.

In some example embodiments, the display device may further include a passivation layer disposed on the light emitting element, the passivation layer being formed of an inorganic material.

In some example embodiments, the coating layer is configured to prevent penetration of moisture and/or oxygen.

In some example embodiments, the display device may further include a dam part surrounding the adhesive layer and disposed in the non-active area. The dam part may include a moisture absorption layer disposed within an interior of the dam part and extending along a longitudinal axis. The dam part may further include base dam portion surrounding the moisture absorption layer such that the moisture absorption layer is disposed within the base dam portion. The base dam portion may have a cylindrical shape. In other embodiments, the base dam portion may have a quadrangular shape and the moisture absorption layer may have any one of a circular shape, a quadrangular shape, and a polygonal shape. The base dam portion may be made of at least one of an epoxy-based sealing material and an acrylic-based sealing material and the moisture absorption layer may be made of a moisture adsorbent. The base dam portion may be configured to block penetration of moisture and/or oxygen while reinforcing adhesiveness between the first substrate and the second substrate.

In other example embodiments, a display device may include a first substrate, a second substrate, and a side sealing part. The first substrate may include an active area in which a light emitting element is disposed and a non-active area surrounding the active area. The second substrate may be disposed above the first substrate. The side sealing part may be positioned such that side sealing part covers a space between the first substrate and the second substrate, a portion of an upper surface of the second substrate, and a side surface of an end portion of the first substrate.

In some example embodiments, the display device further includes a polarizing plate disposed under the first substrate and having an end portion thereof located outside the first substrate and thin film encapsulation layer disposed on the light emitting element and having a plurality of inorganic layers and a plurality of organic layers. The plurality of inorganic layers and the plurality of organic layers of the thin film encapsulation layer may be alternately disposed.

In some example embodiments, the side sealing part may include a first side sealing portion, a second side sealing portion, and a third side sealing portion. The first side sealing portion may be positioned to cover the portion of the upper surface of the second substrate and the space between the first and second substrates. The second side sealing portion may be positioned to cover the end portion of the first substrate while covering a portion of an upper surface of the first substrate. The third side sealing portion may be disposed between the first side sealing portion and the second side sealing portion. The first side sealing portion may be of a frit sealing material and the second side sealing portion and the third side sealing portion may be made of at least one of an epoxy-based resin and an acrylic-based resin.

In some example embodiments, the display device may include a passivation layer made of an inorganic material under the thin film encapsulation layer.

In some example embodiments, the display device may further include a dam part surrounding the adhesive layer and disposed in the non-active area. The dam part may include a moisture absorption layer disposed within an interior of the dam part and extending along a horizontal direction therein longitudinal axis. The dam part may include a base dam portion surrounding the moisture absorption layer such that the moisture absorption layer is disposed within the base dam portion.

In some example embodiments, the base dam portion has a cylindrical shape. The base dam portion may have a quadrangular shape. The moisture absorption layer may have any one of a circular shape, a quadrangular shape, and a polygonal shape. The base dam portion may be made of at least one of an epoxy-based sealing material and an acrylic-based sealing material and the moisture absorption layer may be made of a moisture adsorbent. The base dam portion may be configured to block penetration of moisture and/or oxygen while reinforcing adhesiveness between the first substrate and the second substrate.

As set forth above, specific example embodiments of the present disclosure have been described in more detail with reference to the accompanying drawings. However, the present disclosure is not limited to the foregoing example embodiments, but a variety of modifications are possible without departing from the principle of the present disclosure. Thus, the foregoing example embodiments disclosed herein should be interpreted as being illustrative, while not being limiting, of the principle of the present disclosure, and the scope of the present disclosure is not limited to the foregoing example embodiments. Therefore, the foregoing example embodiments should not be construed as being exhaustive in any aspects.

It will be apparent to those skilled in the art that various modifications and variations can be made in the present disclosure without departing from the spirit or scope of the disclosure. Thus, it is intended that the present disclosure cover such modifications and variations of this disclosure.

What is claimed is:

1. A display device, comprising:
a first substrate including an active area in which a light emitting element is disposed and a non-active area surrounding the active area;
a second substrate disposed on the first substrate; and
a coating layer disposed to contact a portion of the first substrate, and a portion of the second substrate.

2. The display device of claim 1, further comprising an adhesive layer disposed between the first substrate and the second substrate, and
wherein the coating layer is disposed to contact a portion of the adhesive layer.

3. The display device of claim 2, wherein the coating layer is disposed on an end portion of the first substrate, an end portion of the second substrate, and an end portion of the adhesive layer.

4. The display device of claim 3, wherein the coating layer covers at least a portion of an upper surface of the second substrate corresponding to the non-active area.

5. The display device of claim 3, wherein the coating layer covers an entire surface of the second substrate corresponding to the active area and the non-active area.

6. The display device of claim 1, further comprising:
a passivation layer disposed over the light emitting element, the passivation layer being formed of an inorganic material.

7. The display device of claim 1, wherein the coating layer is configured to prevent penetration of moisture and/or oxygen.

8. The display device of claim 2, further comprising a dam part surrounding the adhesive layer and disposed in the non-active area,
wherein the dam part includes a moisture absorption layer disposed within an interior of the dam part and extending along a longitudinal axis.

9. The display device of claim 8, wherein the dam part includes a base dam portion surrounding the moisture absorption layer such that the moisture absorption layer is disposed within the base dam portion,
wherein the base dam portion is made of at least one of an epoxy-based sealing material and an acrylic-based sealing material, and
wherein the moisture absorption layer is made of a moisture adsorbent.

10. The display device of claim 1, further comprising a thin film encapsulation layer disposed over the light emitting element and having a plurality of inorganic layers and a plurality of organic layers.

11. The display device of claim 10, wherein the plurality of inorganic layers and the plurality of organic layers of the thin film encapsulation layer are alternately disposed.

12. A display device, comprising:
a first substrate including an active area in which a light emitting element is disposed and a non-active area surrounding the active area;
a second substrate disposed above the first substrate; and
a side sealing part positioned such that the side sealing part covers a space between the first substrate and the second substrate, a portion of an upper surface of the second substrate, and a side surface of an end portion of the first substrate.

13. The display device of claim 12, further comprising a polarizing plate disposed under the first substrate and having an end portion thereof located outside the first substrate.

14. The display device of claim 12, further comprising a thin film encapsulation layer disposed over the light emitting element and having a plurality of inorganic layers and a plurality of organic layers.

15. The display device of claim 14, wherein the plurality of inorganic layers and the plurality of organic layers of the thin film encapsulation layer are alternately disposed.

16. The display device of claim 12, wherein the side sealing part includes a first side sealing portion positioned to cover the portion of the upper surface of the second substrate and the space between the first and second substrates and, wherein the first side sealing portion is made of a frit sealing material.

17. The display device of claim 16, wherein the side sealing part includes a second side sealing portion positioned to cover the end portion of the first substrate while covering a portion of an upper surface of the first substrate.

18. The display device of claim 17, wherein the side sealing part includes a third side sealing portion disposed between the first side sealing portion and the second side sealing portion and
wherein the second side sealing portion and the third side sealing portion are made of at least one of an epoxy-based resin and an acrylic-based resin.

19. The display device of claim 14, further comprising:
a passivation layer made of an inorganic material under the thin film encapsulation layer.

20. The display device of claim 12, further comprising a dam part surrounding an adhesive layer and disposed in the non-active area, wherein the dam part includes a moisture absorption layer disposed within an interior of the dam part and extending along a horizontal direction therein longitudinal axis,
wherein, the dam part comprises a base dam portion surrounding the moisture absorption layer such that the moisture absorption layer is disposed within the base dam portion,
wherein the base dam portion is made of at least one of an epoxy-based sealing material and an acrylic-based sealing material, and
wherein the moisture absorption layer is made of a moisture adsorbent.
